(19) United States
(12) Patent Application Publication
(10) Pub. No.: US 2016/0155680 A1
(43) Pub. Date: Jun. 2, 2016

(54) Semiconductor Package and Method of Fabrication Thereof

(71) Applicant: Infineon Technologies AG, Neubiberg (DE)

(72) Inventors: Andreas Stueckjuergen, Regensburg (DE); Rainer Leuschner, Regensburg (DE); Daniel Porwol, Straubing (DE)

(21) Appl. No.: 14/954,145

(22) Filed: Nov. 30, 2015

(30) Foreign Application Priority Data
Dec. 1, 2014 (DE) 102014117594.8

(51) Int. Cl. H01L 23/31; H01L 21/56; H01L 21/78; H01L 23/00

(52) U.S. Cl. CPC H01L 23/3157; H01L 24/09; H01L 24/13; H01L 21/565; H01L 24/03; H01L 21/563; H01L 21/78; H01L 21/568; H01L 2224/02381; H01L 2224/02373; H01L 2224/02317; H01L 2924/1811; H01L 2924/182

(57) ABSTRACT

A semiconductor package includes a semiconductor chip having a first main face and side faces, an encapsulation covering at least the side faces of the semiconductor chip, and an electrical redistribution structure arranged over the first main face of the semiconductor chip. A first main surface of the semiconductor package includes a surface of the electrical redistribution structure and a surface of the encapsulation.

### PRIORITY CLAIM

This application claims priority to German Patent Application No. 10 2014 117 594.8 filed on 1 Dec. 2014, the content of said application incorporated herein by reference in its entirety.

### TECHNICAL FIELD

The present application relates to a semiconductor package and to a method for fabricating a semiconductor package.

### BACKGROUND

Semiconductor packages may comprise a semiconductor chip and a redistribution structure for electrically contacting the semiconductor chip. Semiconductor packages may be fabricated by separating single dies from a wafer, rearranging them on a carrier and encapsulating them in an encapsulation. Cost efficient semiconductor packages and methods of fabrication thereof are highly desired in the art. To this end, manufacturing methods providing high yield at low expenses are desirable.

### SUMMARY

According to an embodiment of a semiconductor package, the semiconductor package comprises a semiconductor chip comprising a first main face and side faces, an encapsulation covering at least the side faces of the semiconductor chip, and an electrical redistribution structure arranged over the first main face of the semiconductor chip. A first main surface of the semiconductor package comprises a surface of the electrical redistribution structure and a surface of the encapsulation.

According to another embodiment of a semiconductor package, the semiconductor package comprises a semiconductor chip, a first dielectric layer arranged over a first main surface of the semiconductor chip, and an encapsulation encapsulating at least four side faces of the semiconductor chip and four side faces of the first dielectric layer.

According to an embodiment of a method of fabricating a semiconductor package, the method comprises: providing a semiconductor wafer comprising a first main surface; forming a plurality of electrical redistribution structures over the first main surface of the semiconductor wafer; singularizing the semiconductor wafer into multiple semiconductor chips, each semiconductor chip being provided with an electrical redistribution structure; placing the semiconductor chips in a spaced-apart relationship on a temporary carrier; filling the spaces between the semiconductor chips and electrical redistribution structures with an encapsulant; and cutting along the spaces.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 shows a cross-sectional view of an embodiment of a semiconductor package.

FIGS. 2A-2I show cross-sectional views of a semiconductor package in various stages of production according to an embodiment of a method of fabricating a semiconductor package.

FIG. 3 shows a cross-sectional view of a further embodiment of a semiconductor package.

FIGS. 4A-4E show cross-sectional views of a further semiconductor package in various stages of production according to an embodiment of a method of fabricating a semiconductor package.

FIG. 5 shows a top-down view of an array of semiconductor packages according to the disclosure.

FIG. 6 shows a flow-chart diagram of an embodiment of a method of fabricating a semiconductor package according to the disclosure.

### DETAILED DESCRIPTION

In the following Detailed Description, reference is made to the accompanying drawings, which form a part thereof, and in which are shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the concept of the present invention. The following detailed description, therefore, is not to be taken in a limiting sense, and the concept of the present invention is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

Devices or packages containing semiconductor chips are described below. The semiconductor chips may be of different types, may be manufactured by different technologies and may include for example integrated electrical, electro-optical or electro-mechanical circuits and/or passives. The semiconductor chips may, for example, be designed as logic integrated circuits, analog integrated circuits, mixed signal integrated circuits, power integrated circuits, memory circuits or integrated passives. They may include control circuits, microprocessors or microelectromechanical components. Further, they may be configured as power semiconductor chips, such as power MOSFETs (Metal Oxide Semiconductor Field Effect Transistors), IGBTs (Insulated Gate Bipolar Transistors), JFETs (Junction Gate Field Effect Transistors), power bipolar transistors or power diodes. In particular, semiconductor chips having a vertical structure may be involved, that is to say that the semiconductor chips may be fabricated in such a way that electric currents can flow in a direction perpendicular to the main faces of the semiconductor chips. A semiconductor chip having a vertical structure may have contact elements in particular on its two main faces, that is to say on its top side and bottom side. In particular, power semiconductor chips may have a vertical structure. By way of example, the source electrode and gate electrode of a power MOSFET may be situated on one main face, while the drain electrode of the power MOSFET is arranged on the other main face. Furthermore, the devices described below may include integrated circuits to control the integrated circuits of other semiconductor chips, for example the integrated circuits of power semiconductor chips. The semiconductor chips need not be manufactured from specific semiconductor material, for example Si, SiC, SiGe, GaAs, GaN, AlGaAs and, furthermore, may contain inorganic and/or organic materials that are not semiconductors, such as for example insulators, plastics or metals.

The devices described below include external contact elements or external contact pads on package. The external contact pads may represent the external terminals of the semiconductor package. They may be accessible from outside the package and may thus allow electrical contact to be made with the semiconductor chip(s) from outside the package. Furthermore, the external contact pads may be thermally conductive and may serve as heat sinks for dissipating the heat generated by the semiconductor chip or chips embedded in the semiconductor package. The external contact pads may be composed of any desired electrically conductive material, for example of a metal, such as copper, aluminum or gold, a metal alloy or an electrically conductive organic material. Solder material, such as solder balls or solder bumps, may be deposited on the external contact pads.

The semiconductor chips or at least parts of the semiconductor chips are covered with an encapsulating material (encapsulant) to form an encapsulation (e.g. a molded body), which may be electrically insulating. The encapsulant may comprise or be a dielectric material and may be made of any appropriate duroplastic, thermoplastic or thermosetting material or laminate (prepreg). The encapsulant may contain filler materials. After its deposition, the encapsulant may be only partially hardened and may be completely hardened after application of energy (e.g. heat, UV light, etc.) to form an encapsulation. Various techniques may be employed to cover the semiconductor chips with the encapsulation, for example compression molding, injection molding, powder molding, liquid molding, dispensing or laminating.

The semiconductor chips may be provided with an electrical redistribution structure. The electrical redistribution structure may comprise one or more polymer layers. The polymer layer(s) may be applied during wafer level processing, that is during front-end processing. By way of example, the polymer layer(s) may be applied by a CVD (Chemical Vapor Deposition) process or by a spin coating process. The polymer layer(s) may be made of a photoresist or of any other etching resist. For example, a photoimide may be used. In particular, filler materials such as e.g. organic or mineral filler materials may be included in the polymer layer(s). The filler material may improve the CTE (coefficient of thermal expansion) to decrease stress and warpage of the package and may improve the protective effect of the polymer layer(s) to the semiconductor chip surface covered by the polymer layer(s).

The electrical redistribution structure may comprise one or more conductive layers, e.g. metal layers. The conductive layers may, for example, be used to form a redistribution layer within the redistribution structure. The conductive layer(s) may be used as wiring layer(s) to make electrical contact with the semiconductor chip(s) from outside the package and/or to make electrical contact with one or more other semiconductor chip(s) and/or components contained in the package. The conductive layer(s) maybe manufactured with any desired material composition and structured to any desired geometric shape. The conductive layer(s) may, for example, be composed of conductor tracks and/or pads and may, e.g., cover a substantial area of the footprint of the semiconductor chip(s). The conductive layer(s) maybe used to provide the external contact pads of the package. Any desired metal, for example aluminum, nickel, palladium, silver, tin, gold or copper, or metal alloys may be used as the material. The conductive layers need not be homogenous or manufactured from just one material, that is to say various compositions and concentrations of the materials contained in the conductive layers are possible. Thin-film technologies may be applied to generate and/or structure the conductive layers.

The conductive layer(s) may be arranged above or below or between electrically insulating layers (also termed dielectric layers herein) forming part of the redistribution structure. An insulating layer overlaying a conductive layer, e.g. the uppermost insulating layer, may be used as a solder stop layer.

The conductive layer(s) may be arranged directly above a hard passivation layer of the semiconductor wafer according to an embodiment. According to another embodiment, a further dielectric layer of the redistribution structure may be arranged between the hard passivation layer and the conductive layer(s). The further dielectric layer may comprise a polymer layer. The hard passivation layer is an inorganic dielectric layer such as, e.g., a layer comprising silicon oxide, silicon nitride, or an oxide-nitride composition.

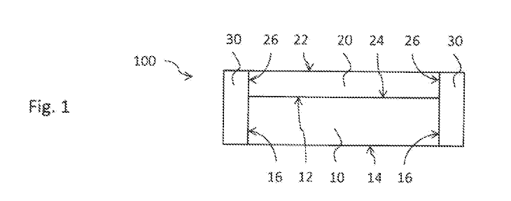

FIG. 1 shows a semiconductor device or semiconductor package 100. Semiconductor package 100 comprises a semiconductor chip 10, a redistribution structure 20, and an encapsulation 30. Semiconductor chip 10 may comprise a first main face 12, a second main face 14 opposite the first main face 12, and, e.g., four side faces 16 extending between the first and second main faces 12, 14. Redistribution structure 20 may be arranged above the first main face 12 of semiconductor chip 10 such that a lower main face 24 of redistribution structure 20 may be in direct contact with the first main face 12. Encapsulation 30 may be arranged on all (four) sides of semiconductor chip 10 and redistribution structure 20 such that side faces 16 of semiconductor chip 10 and side faces 26 of redistribution structure 20 are least partially or completely covered by encapsulation 30.

According to an embodiment, the upper main face 22 of the redistribution structure 20 and an upper surface of the encapsulation 30 are flush. This case is shown in FIG. 1. According to another embodiment, semiconductor package 100 comprises a height difference in a direction facing away from the first main face 12 of semiconductor chip 10 between the upper main face 22 of redistribution structure 20 and the upper surface of the encapsulation 30. In particular, upper main face 22 of redistribution structure 20 may be higher than the upper surface of the encapsulation 30 in a direction facing away from the first main face 12 of the semiconductor chip 10.

Redistribution structure 20 may comprise at least a first dielectric layer and an electrical redistribution layer arranged over the first dielectric layer. Upper main face 22 may comprise a surface of the redistribution layer, for example at least one solder pad. The first dielectric layer may comprise a hard passivation layer, a polymer layer, and/or a photoimide.

Redistribution structure 20 may comprise a second dielectric layer arranged over the electrical redistribution layer such that upper main face 22 comprises a surface of the second dielectric layer. The second dielectric layer may be a solder stop layer and it may comprise a polymer or a photoimide. The dielectric layer(s) of redistribution structure 20 may each comprise a low-k material.

In a top view down on upper main face 22, an outline of the first main face 12 of the semiconductor chip 10 and an outline of redistribution structure 20 may overlap. According to an embodiment, at least the outline of the first main face 12 of the semiconductor chip 10 and an outline of the first dielectric layer may overlap.

Encapsulation 30 may comprise lateral walls that completely cover the side faces 16 of the semiconductor chip 10. The walls may project over the first main face 12 of the semiconductor chip 10 such that lateral side faces 26 of redistribution structure 20 abut to lateral faces of the walls and are partially or even completely covered by the walls. The walls may only have a minimum thickness necessary for sufficiently protecting the semiconductor chip 10 and/or the redistribution structure 20, because encapsulation 30 does not need to support any form of redistribution structure. The walls may have any appropriate thickness, for example a thickness equal to or greater than or less than 20 μm, 40 μm, 60 μm, 80 μm, 100 μm, 120 μm, 150 μm.

According to an embodiment, encapsulation 30 may further comprise a bottom wall, wherein the bottom wall encapsulates semiconductor chip 10 on the second main face 14 (not shown in FIG. 1). The bottom wall may completely cover the second main face 14 of the semiconductor chip 10. The lateral walls and the bottom wall of the encapsulation 30 may be integral, i.e. parts of a single contiguous piece. Encapsulation 30 may comprise any appropriate mold material and/or laminate known in the art.

First main face 12 of semiconductor chip 10 may comprise at least one contact element or electrode (not shown in FIG. 1) and the redistribution structure 20 may comprise an electrical redistribution layer for electrically connecting the at least one contact element to at least one outer contact package terminal contact of the semiconductor package 100 (also not shown in FIG. 1). The outer package terminal contact(s) may be arranged on the upper main face 22 of the redistribution structure 20. Encapsulation 30, in particular the upper surface of the encapsulation 30, may be free of any outer package terminal contacts and/or any redistribution layer. In other words, the semiconductor package 100 may essentially be a fan-in type package, wherein the redistribution structure and the outer package terminal contacts are arranged inside the footprint of the semiconductor chip 10 and/or inside the inside outline of the lateral walls of the encapsulation 30.

Alternatively or additionally to contact elements arranged on the first main face 12, one or more second contact elements may be arranged on the second main face 14 of semiconductor chip 10. The second contact elements may be connected to outer package terminal contacts using vias, for example Through-Silicon-Vias (TSVs).

Semiconductor chip 10 may have a thickness measured from the first main face 12 to second main face 14 equal to or less or greater than 50 μm, 100 μm, 150 μm or 200 μm, or any other appropriate thickness above or below these values.

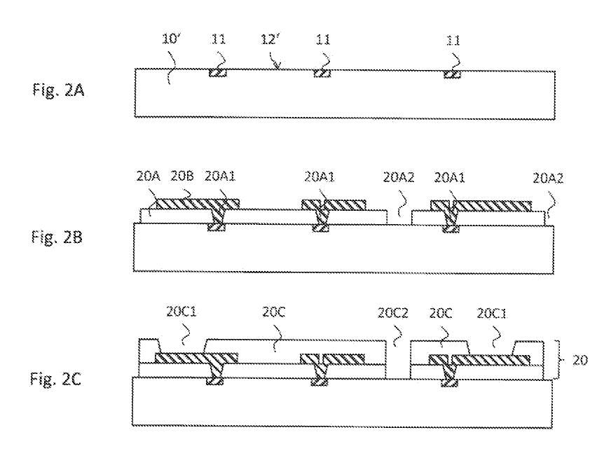

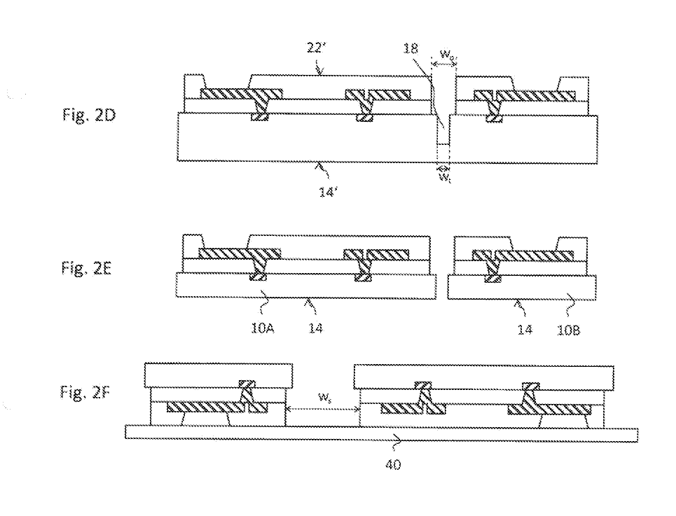

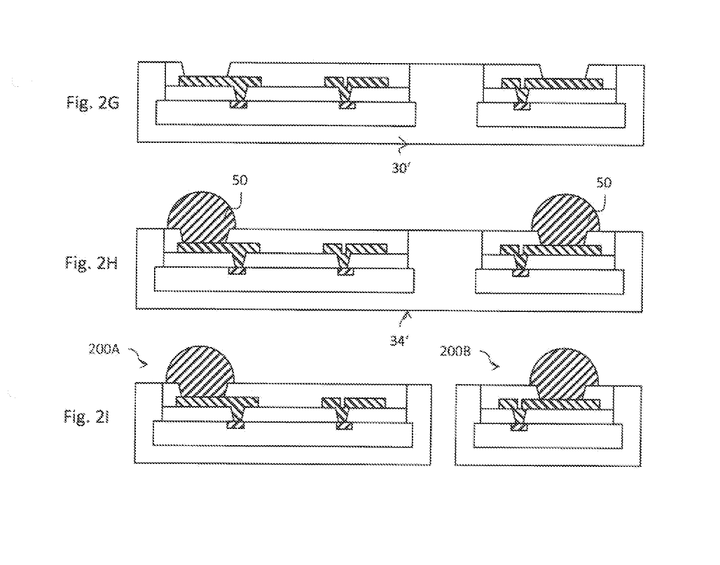

FIGS. 2A-2I show a method of fabricating semiconductor packages 200A, 200B depicted in FIG. 2I, which may correspond to semiconductor package 100. The above disclosure related to semiconductor package 100 may also be applied to semiconductor packages 200A, 200B and vice versa, and reiteration is avoided for the sake of brevity.

FIG. 2A shows a semiconductor wafer 10′. Semiconductor wafer 10′ may comprise bulk silicon in which integrated circuits are embedded. Contact elements 11 for electrically contacting the integrated circuits may be arranged on a first main face 12′ of the semiconductor wafer 10′.

A wafer-level redistribution structure may be arranged above first main face 12′ of semiconductor wafer 10′. FIG. 2B shows a first dielectric layer 20A which is part of the waver-level redistribution structure applied on first main face 12′. First dielectric layer 20A may be structured to comprise first openings 20A1 and may, e.g., further comprise second openings 20A2. First openings 20A1 may be arranged over the contact elements 11 of semiconductor wafer 10′. Second openings 20A2 may have the form of a rectangular pattern of straight lines on first main face 12′ and may be arranged over areas of the semiconductor wafer 10′ that do not comprise integrated circuits. Byway of example, the second openings 20A2 may basically form a checkerboard pattern on the semiconductor wafer 10′.

The structured first dielectric layer 20A may be fabricated by selectively applying dielectric layer 20A onto semiconductor wafer first main face 12′, or by applying lithographic techniques like photolithography to structure a uniformly applied dielectric layer. Spin coating or CVD techniques may, e.g., be used for uniformly applying a dielectric layer onto semiconductor wafer first main face 12′.

The wafer-level redistribution structure further comprises a plurality of electrically conducting redistribution layers 20B applied side-by-side over the first dielectric layer 20A. According to an embodiment, the electrical redistribution layers 20B may be applied after first dielectric layer 20A has been applied to semiconductor wafer first main face 12′. Redistribution layers 20B may be selectively applied or may be structured using well known techniques, for example lithographic techniques. The electrical redistribution layers each form part of one of the plurality of electrical redistribution structures.

Redistribution layers 20B may be configured to fill first openings 20A1 of the first dielectric layer 20A. The redistribution layers 20B may further provide solder bonding pads configured for the accommodation of solder balls as described further below.

According to an embodiment, each of the redistribution layers 20B may comprise at least a first metal layer and a second metal layer arranged over the first metal layer. The first metal layer may be configured as a barrier layer. The first metal layer may, e.g., comprise TiW or another barrier metal or metal composition.

According to an embodiment, the first dielectric layer 20A is a polymer layer and a hard passivation layer is arranged between the first dielectric layer 20A and the first main face 12′ of semiconductor chip 10′ (not shown). According to another embodiment, the first dielectric layer 20A is the hard passivation layer, and no polymer layer is arranged between the redistribution layers 20B and the first main face 12′ of semiconductor chip 10′.

In a next step, a second dielectric layer 20C may be applied on top of first dielectric layer 20A and the redistribution layers 20B as shown in FIG. 2C. The second dielectric layer 20C may comprise the same material or material composition as first dielectric layer 20A. The same means of application as disclosed with respect to the first dielectric layer 20A may be used for applying the second dielectric layer 20C, and reiteration is therefore avoided.

First dielectric layer 20A may, for example, have a thickness in the range of 3 μm-10 μm, in particular about 7 μm. Redistribution layer 20B may, for example, have a thickness in the range of 3 μm-10 μm, in particular 7 μm. Second dielectric layer 20C may for example have a thickness in the range of 2 μm-7 μm, in particular 3 μm-5 μm.

Second dielectric layer 20C may comprise structural elements like first openings 20C1 and second openings 20C2. First openings 20C1 may be arranged over flat surface areas of the redistribution layer 20B that are designated as solder bonding pads. Second openings 20C2 may be arranged over second openings 20A2 of the first dielectric layer 20A. In particular, second openings 20C2 of the second dielectric layer 20C may be congruent with second openings 20A2 of the first dielectric layer 20A. Note that second openings 20A2 and 20C2 may exhibit some deviations from congruence which may be due to fabrication tolerances.

According to an embodiment, the second dielectric layer 20C may be configured as a solder stop layer.

In a subsequent process step, as shown in FIG. 2D, trenches 18 may be formed in the first main face 12′ of semiconductor wafer 10′. In particular, trenches 18 may be formed along second openings 20A2, 20C2. Trenches 18 may be formed by any appropriate technique, for example by sawing, cutting, etching, for example plasma etching, or laser ablation. Techniques resulting in a small width wₜ of trenches 18 may be preferred. Such techniques are termed “narrow-kerf” techniques in the art.

The width wₜ may be smaller than the width wₒ of the second openings 20A2, 20C2 as shown in FIG. 2D. Alternatively, the width wₜ of trenches 18 may also be identical to the width wₒ of second openings 20A2, 20C2. The width wₜ may, for example, lie in the range of 8 μm-30 μm, in particular in the range of 12 μm-20 μm. Trenches 18 may have any appropriate depth, for example a depth in the range of 150 μm-200 μm. The depth may, however, also be greater than or less than this range.

After the formation of trenches 18, a grinding process may be applied to second main face 14′ of semiconductor wafer 10′, thereby thinning the wafer 10′. This order of processes is known as “Dicing Before Grinding” (DBG) in the art. During grinding, the semiconductor wafer 10′ may be attached to a temporary carrier like, for example, an adhesive foil or a vacuum chuck such that the upper surface 22′ of second dielectric layer 200 is in contact with the temporary carrier. The level of the ground second main face 14 may lie within the depth of trenches 18. In other words, by grinding the semiconductor wafer 10′ may be singularized into a plurality of semiconductor chips 10A, 10B as shown in FIG. 2E.

According to another embodiment, the singularization of the semiconductor chips 10A, 10B does not involve a grinding process. For example, instead of trenches 18, corresponding openings 18 may be formed to completely cut through wafer 10′.

After singularization, the singularized semiconductor chips 10 may be arranged on a further temporary carrier 40 in a spaced apart relationship as shown in FIG. 2F. Furthermore, arranging the semiconductor chips 10 on the temporary carrier 40 may be performed in an upside-down manner as shown in FIG. 2F. According to an embodiment, arranging the singularized semiconductor chips on the temporary carrier 40 comprises a pick-and-place process. Spacings wₛ between individual semiconductor chips 10 may be wider than the width wₜ of trenches 18. Spacings wₛ may have any appropriate width and may, for example, lie in the range of 150 μm-400 μm, or even above or below this range. The temporary carrier 40 may comprise a plate made of a rigid material, for example a metal, metal alloy, silicon, glass or plastic. Temporary carrier 40 may further comprise an adhesive foil, glue, means for creating a vacuum, a clamping mechanism, or any other appropriate adhesion means for adhering the singularized semiconductor chips 10 to the surface of temporary carrier 40.

Subsequently, encapsulation material (or encapsulant) is applied to the semiconductor chips 10 attached to temporary carrier 40. The encapsulation material may cover the side faces 16 of semiconductor chips 10 and the side faces 26 of the redistribution structures 20. The encapsulation material may completely fill the spaces between the individual semiconductor chips 10 and the individual redistribution structures 20. Additionally, the encapsulation material may, e.g., cover the second main face 14 of semiconductor chips 10.

For example, the encapsulation material may be a duroplastic or thermosetting mold material. The encapsulation material maybe based on an epoxy material and may contain a filling material consisting of small particles of glass (SiO₂) or other electrically insulating mineral filler materials like Al₂O₃ or organic filler materials. The encapsulation material maybe based on a polymer material. After curing, the encapsulation material provides stability to the array of semiconductor chips 10. Various techniques maybe employed to cover the semiconductor chips 10 with the encapsulation material. The encapsulation material (mold material) may, for example, be applied by compression molding, injection molding, granulate molding, powder molding or liquid molding.

By way of example, in a compression molding process, the liquid encapsulation material is dispensed into an open lower mold half of which the temporary carrier 40 forms the bottom. Then, after dispensing the liquid encapsulation material, an upper mold half is moved down and spreads out the liquid encapsulation material until a cavity between the temporary carrier 40 forming the bottom of the lower mold half and the upper mold half is completely filled. This process may be accompanied by the application of heat and pressure. After curing, the encapsulation material is rigid and forms the molded body or encapsulation body 30′. The larger the lateral size of the molded body and the number of embedded semiconductor chips 10, the more cost efficient the process will typically be. The result of the encapsulation process is shown in FIG. 2G.

According to one embodiment, a polymer material is used to encapsulate the semiconductor chips 10 and to form the encapsulation body 30′. The polymer material may have the shape of an electrically insulating foil or sheet, which is laminated on top of the semiconductor chips 10 as well as the temporary carrier 40. Heat and pressure may be applied for a time suitable to attach the polymer foil or sheet to the underlying structure. The gaps between the semiconductor chips 10 are also filled with the polymer material. The polymer material may, for example, be a prepreg (short for preimpregnated fibers) that is a combination of a fiber mat, for example glass or carbon fibers, and a resin, for example a duroplastic material. Prepreg materials are usually used to manufacture PCBs (printed circuit boards). Prepreg materials are bi-stage materials, which are flexible when applied over the semiconductor chips 10 and harden during a heat-treatment. For the lamination of the prepreg the same or similar process steps can be used as in PCB manufacturing.

After the encapsulation step the encapsulation body 30′ comprising the semiconductor chips 10 may be removed from the temporary carrier 40.

Subsequently, as shown in FIG. 2H, outer package terminal contacts 50 may be formed. Outer package terminal contacts may comprise solder balls. Solder balls may be applied using the so-called “ball placement” technique, wherein pre-shaped balls composed of solder material are applied to contact pads of the redistribution layers 20B. Alternatively, solder balls 50 may, for example, be applied using stencil printing with a solder paste followed by a heat-treatment process.

The solder material may comprise Sn, SnPb, SnAg, SnAgCu, SnAgCuNi, SnAu, SnCu and SnBi. The solder balls 50 may be used to electrically couple the semiconductor packages 200A, 200B to other components, for example a PCB. An upper surface of the solder balls 50 may, for example, project about 200 pm or more beyond the upper surface 22′ of the second dielectric layer 20C.

According to an embodiment of a method of fabricating semiconductor packages, the encapsulation body 30′ may be subjected to a grinding process. That is, a lower surface 34′ of the encapsulation body 30′ may be ground in order to form an encapsulation body 30′ of a reduced, predefined thickness. The grinding process may be performed before or after the application of outer package terminal contacts, e.g. solder balls 50. That is, grinding may be performed on the intermediate product of FIG. 2G or FIG. 2H.

After application of outer package terminal contacts 50, the encapsulation body 30′ comprising the semiconductor chips 10 may be singularized into a plurality of semiconductor packages 200A, 200B as shown in FIG. 21. The same singularization techniques as disclosed above with respect to singularizing semiconductor wafer 10′ into semiconductor chips 10 may be used. For the singularization process, the encapsulation body 30′ may be placed on a support such that a lower surface 34′ of the encapsulation body 30′ faces the support. The encapsulation body 30′ may further be adhered to the support, for example by means of an adhesive foil, a glue, a vacuum, or a clamping mechanism.

As shown in FIGS. 2A-2I, the semiconductor wafer 10′ may comprise a plurality of diverse integrated circuits configured to be integrated into diverse semiconductor packages like semiconductor packages 200A, 200B. However, semiconductor wafer 10′ may also comprise a plurality of identical integrated circuits.

The method of fabricating a semiconductor package as shown in FIGS. 2A-2I may essentially combine techniques of Wafer Level Package (WLP) fabrication with techniques of extended Wafer Level Ball grid array (eWLB) fabrication. In the method of fabricating a semiconductor package, WLP techniques are used up to and including the application of the redistribution structure, whereas eWLB techniques may subsequently be used for the solder ball application. The final product, that is semiconductor packages 200A, 200B, may, e.g., be a fan-in eWLB type package.

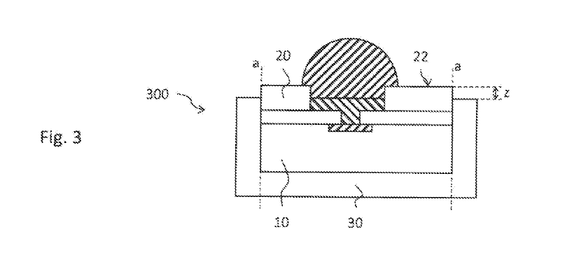

FIG. 3 shows a semiconductor package 300 which may be fabricated by the method shown with respect to FIGS. 2A-2I and which may be identical or similar to semiconductor packages 100, 200A, 200B. However, semiconductor package 300 shows a height difference z between upper main face 22 of the redistribution structure 20 and an upper surface of the encapsulation 30. Height difference z may stem from the fact that when adhering redistribution structure 20 to temporary carrier 40 (FIG. 2F), redistribution structure 20 may be slightly pushed into a sticky material like an adhesion foil or a glue on the surface of the carrier 40. In this case the sticky material may cover an end portion of the redistribution structure side faces 26 up to a height z as measured from the upper main face 22. During the subsequent encapsulation process the encapsulation material therefore cannot encapsulate the portion of the side faces 26 that is covered by the sticky material.

On the other hand, it is also possible that during the encapsulation process the encapsulation material may “bleed” into the interface between temporary carrier 40 and upper main face 22. For instance, “bleeding” could occur if the adhesion force between the temporary carrier 40 and the upper main face 22 of redistribution structure 20 is relatively small. In this case, encapsulation 30 may at least partially encapsulate the redistribution structure 20 on the upper main face 22.

According to an embodiment of a method for fabricating a semiconductor package, a grinding process may be applied to the upper main face 22 in order to remove height difference z. Grinding may be performed before singularizing the encapsulation body 30′.

Side faces 16 of semiconductor chip 10 and side faces 26 of redistribution structure 20 may be displaced as shown in semiconductor packages 200A, 200B, wherein viewed from above first main face 22, an outline of redistribution structure 20 is completely surrounded by an outline of semiconductor chip 10. However, it is also possible that side faces 16 and 26 are flush, that is, side faces 16 and 26 are located in a common plane as shown in FIG. 3.

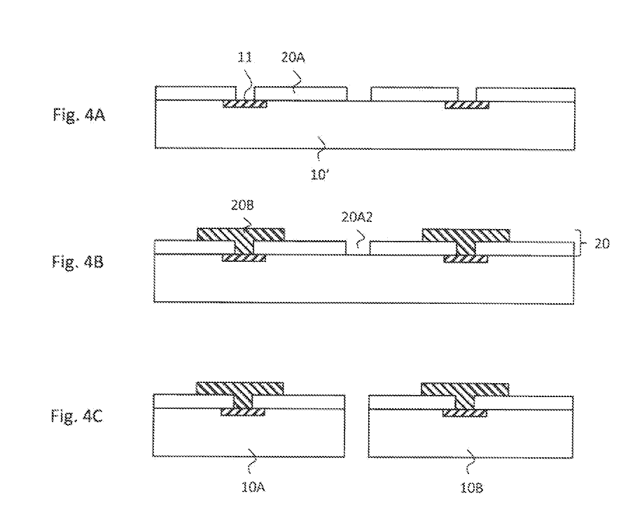

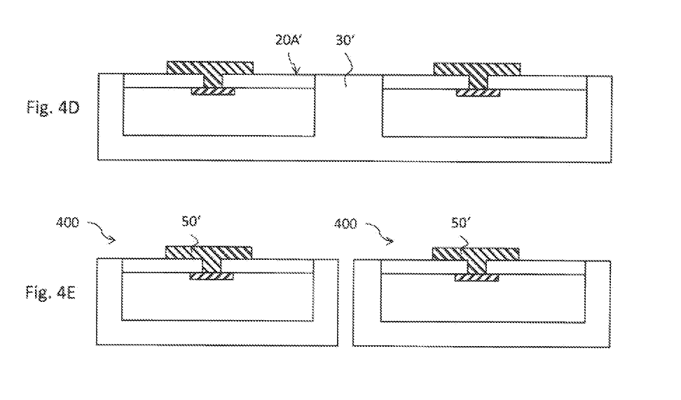

With respect to FIGS. 4A-4E a further embodiment of a method for fabricating a semiconductor package 400 is shown. Semiconductor package 400 may be identical to semiconductor packages 100, 200A, 200B and 300 except that redistribution structure 20 of semiconductor package 400 does not comprise a second dielectric layer 20C. Similar method steps as disclosed with respect to FIGS. 2A-2I may be used in the embodiment of the method shown in FIGS. 4A-4E.

FIG. 4A shows a semiconductor wafer 10′ comprising contact elements 11 and a first dielectric layer 20A arranged above semiconductor wafer 10′. According to an embodiment, dielectric layer 20A may comprise a hard passivation layer. According to an embodiment, dielectric layer 20A may solely be a hard passivation layer.

In FIG. 4B a plurality of redistribution layers 20B arranged over dielectric layer 20A and semiconductor wafer 10′ is shown. Dielectric layer 20A and redistribution layers 20B together form a plurality of redistribution structures 20 arranged side-by-side over the semiconductor wafer 10′. According to an embodiment, redistribution layer 20B may comprise an Under Bump Metallization (UBM). According to another embodiment, redistribution layer 20B may solely be a UBM. The UBM may serve as a substrate for the application of a solder ball.

Subsequently to forming the electrical redistribution layers 20B, semiconductor wafer 10′ may be singularized into individual semiconductor chips 10A, 10B as shown in FIG. 4C. Singularization may comprise forming trenches along second openings 20A2 in dielectric layer 20A and may further comprise a grinding process.

After singularization of semiconductor wafer 10′ into semiconductor chips 10, an encapsulation process maybe performed, wherein an encapsulation body 30′ (e.g. a molded body) is formed as shown in FIG. 4D. The encapsulation material may form walls encapsulating the semiconductor chips on the semiconductor chip side faces 16. Additionally, the encapsulation body 30′ may encapsulate the semiconductor chip second main faces 14. The encapsulation body 30′ may partly or completely encapsulate the side faces of redistribution structure 20. In particular, the encapsulation body 30′ may partly or completely cover the side faces of dielectric layer 20A and may not cover side faces of redistribution layer 20B, which may then remain exposed. Alternatively, encapsulation body 30′ may further partly or completely cover side faces of redistribution layer 20B. In this case, the encapsulation body 30′ may also encapsulate or partly encapsulate the first main face 20A′ of dielectric layer 20A.

After encapsulation, semiconductor packages 400 as shown in FIG. 4E may be singularized from encapsulation body 30′. According to an embodiment, semiconductor packages 400 comprise flat outer package terminal contacts 50′ as shown in FIG. 4E. According to another embodiment, semiconductor packages 400 may comprise solder balls 50 configured as outer package terminal contacts as for example illustrated in FIG. 3. The solder balls 50 may be applied previous to singularizing encapsulation body 30′.

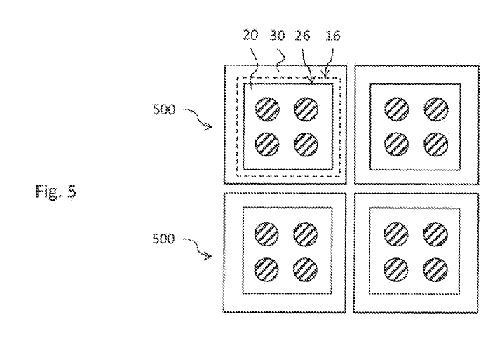

FIG. 5 shows a top down view of an array of semiconductor packages 500. The semiconductor packages 500 may correspond to semiconductor packages 100, 200A, 200B, 300, or 400. Such an array of semiconductor packages may be the result of the semiconductor package singularization step disclosed with respect to FIGS. 2I and 4E.

FIG. 5 shows how encapsulation 30 comprises walls that encapsulate all side faces 26 of the redistribution structure 20. As already mentioned above, each side face 16 of semiconductor chip 10 may be flush with the respective side face 26 of the redistribution structure 20. Alternatively, the redistribution structure side faces 26 may lie within a footprint of semiconductor chip 10. This case is depicted by the dashed lines in FIG. 5 which correspond to semiconductor chip side faces 16.

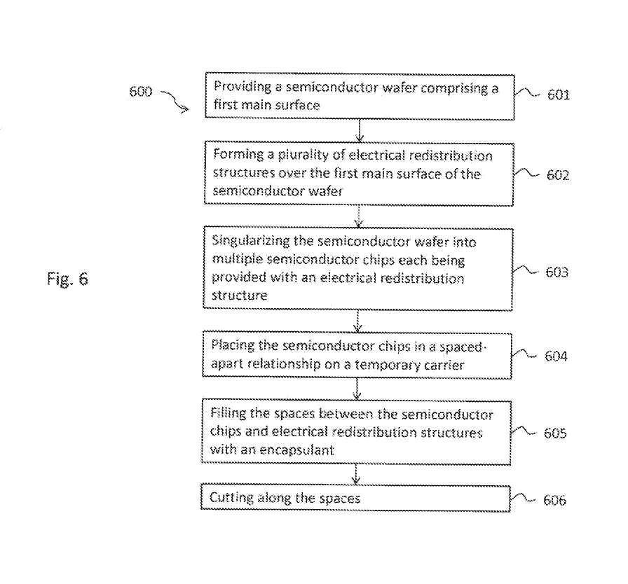

In FIG. 6 a flow chart of a method 600 of fabricating a semiconductor package is shown. Method 600 may be used to fabricate semiconductor packages 100, 200A, 200B, 300 and 400. At 601, the method 600 may comprise providing a semiconductor wafer comprising a first main surface. At 602, the method 600 may comprise forming a plurality of electrical redistribution structures over the first main surface of the semiconductor wafer. At 603, the method 600 may comprise singularizing the semiconductor wafer into multiple semiconductor chips, each being provided with an electrical redistribution structure. At 604, the method 600 may comprise placing the semiconductor chips in a spaced-apart relationship on a temporary carrier. At 605, the method 600 may comprise filling the spaces between the semiconductor chips and electrical redistribution structures with an encapsulant. At 606, the method 600 may comprise cutting along the spaces.

One further feature of method 600 may comprise applying a redistribution structure to a semiconductor chip before encapsulating the semiconductor chip with an encapsulation. Another further feature of method 600 may comprise attaching solder deposits to the plurality of electrical redistribution structures (“ball placement”). Attaching the solder deposits may be performed after filling the spaces between the semiconductor chips and electrical redistribution structures.

In addition, while a particular feature or aspect of an embodiment of the invention may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the invention may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the concept of the present invention. This application is intended to cover any adaptations or variations of the specific embodiments discussed herein. Therefore, it is intended that this invention be limited only by the claims and the equivalents thereof.

What is claimed is:

1. A semiconductor package, comprising:
a semiconductor chip comprising a first main face and side faces;
an encapsulation covering at least the side faces of the semiconductor chip; and
an electrical redistribution structure arranged over the first main face of the semiconductor chip,
wherein a first main surface of the semiconductor package comprises a surface of the electrical redistribution structure and a surface of the encapsulation.

2. The semiconductor package of claim 1, wherein the encapsulation further encapsulates the semiconductor chip on a second main face of the semiconductor chip opposite the first main face.

3. The semiconductor package of claim 1, wherein the electrical redistribution structure comprises a dielectric layer and an electrical redistribution layer arranged over the dielectric layer, and wherein the surface of the electrical redistribution structure comprises a surface of the electrical redistribution layer.

4. The semiconductor package of claim 3, wherein the dielectric layer is a hard passivation layer, a polymer layer or a photoimide.

5. The semiconductor package of claim 1, wherein the electrical redistribution structure comprises an electrical redistribution layer and a dielectric layer arranged over the electrical redistribution layer, and wherein the surface of the electrical redistribution structure comprises a surface of the dielectric layer.

6. The semiconductor package of claim 5, wherein the dielectric layer is a solder stop layer.

7. The semiconductor package of claim 1, wherein the first main surface of the semiconductor package comprises at least one outer package terminal contact.

8. The semiconductor package of claim 7, wherein the at least one outer package terminal contact comprises a solder ball.

9. The semiconductor package of claim 1, wherein the encapsulation comprises a mold material or a laminate.

10. The semiconductor package of claim 1, wherein the encapsulation comprises walls covering the side faces of the semiconductor chip and projecting over the first main face of the semiconductor chip, and wherein lateral faces of the electrical redistribution structure abut to lateral faces of the walls.

11. The semiconductor package of claim 10, wherein the walls of the encapsulation completely surround the semiconductor chip and the electrical redistribution structure.

12. The semiconductor package of claim 1, wherein in a direction facing away from the first main face of the semiconductor chip, the surface of the electrical redistribution structure is higher than the surface of the encapsulation.

13. A semiconductor package, comprising:
a semiconductor chip;
a first dielectric layer arranged over a first main surface of the semiconductor chip; and
an encapsulation encapsulating at least four side faces of the semiconductor chip and four side faces of the first dielectric layer.

14. The semiconductor package of claim 13, wherein an outline of the first main surface of the semiconductor chip and an outline of the first dielectric layer overlap.

15. The semiconductor package of claim 13, further comprising:
an electrical redistribution layer arranged over the first dielectric layer; and
a second dielectric layer arranged over the electrical redistribution layer,
wherein the encapsulation further encapsulates at least four side faces of the electrical redistribution layer and at least four side faces of the second dielectric layer.

16. A method of fabricating a semiconductor package, the method comprising:
providing a semiconductor wafer comprising a first main surface;
forming a plurality of electrical redistribution structures over the first main surface of the semiconductor wafer;
singularizing the semiconductor wafer into multiple semiconductor chips, each semiconductor chip being provided with an electrical redistribution structure;
placing the semiconductor chips in a spaced-apart relationship on a temporary carrier;
filling the spaces between the semiconductor chips and electrical redistribution structures with an encapsulant; and
cutting along the spaces.

17. The method of claim 16, wherein forming a plurality of electrical redistribution structures over the first main surface of the semiconductor wafer comprises:
forming a first dielectric layer over the first main surface of the semiconductor wafer; and
forming and structuring an electrically conducting layer over the first main surface of the semiconductor wafer to provide for a plurality of electrical redistribution layers each forming part of one of the plurality of electrical redistribution structures.

18. The method of claim 17, further comprising:
forming a second dielectric layer arranged over the plurality of electrical redistribution layers before singularizing the semiconductor wafer into multiple semiconductor chips.

19. The method of claim 16, further comprising:
attaching solder deposits to the plurality of electrical redistribution structures, wherein attaching the solder deposits is performed after filling the spaces.

20. The method of claim 16, wherein singularizing the semiconductor wafer comprises:
forming trenches in the first main surface of the semiconductor wafer; and
grinding a second main surface of the semiconductor wafer opposite the first main surface.
